(19) United States
(12) Patent Application Publication
(10) Pub. No.: US 2025/0374443 A1
(43) Pub. Date: Dec. 4, 2025

(54) POWER SUPPLY

(71) Applicant: Lite-On Technology Corporation, Taipei (TW)

(72) Inventors: Yu-Hung Kuo, Taipei (TW); Yu-Jen Wei, Taipei (TW); Tsung-Po Hsu, Taipei (TW); Yu-Sian Lin, Taipei (TW)

(73) Assignee: Lite-On Technology Corporation, Taipei (TW)

(21) Appl. No.: 18/761,213

(22) Filed: Jul. 1, 2024

(30) Foreign Application Priority Data
May 30, 2024 (CN) 202421214118.X

(51) Int. Cl. H05K 5/00; H05K 5/02; H05K 5/03; H05K 7/20

(52) U.S. Cl. CPC H05K 5/0052; H05K 5/0213; H05K 5/03; H05K 5/13; H05K 7/20172

(57) ABSTRACT

The disclosure provides a power supply including a first cover, a circuit board, and a second cover. The first cover has four first assembly holes, the circuit board is locked to the first assembly holes of the first cover, the second cover is closed with the first cover, and the circuit board is located in a space formed by the first cover and the second cover.

### CROSS-REFERENCE TO RELATED APPLICATION

This application claims the priority benefit of China application serial no. 202421214118.X, filed on May 30, 2024. The entirety of the above-mentioned patent application is hereby incorporated by reference herein and made a part of this specification.

### BACKGROUND

### Technical Field

This disclosure relates to an electronic device, in particular to a power supply.

### Description of Related Art

The current design of the power supply has a lot of seams on the exterior of the casing, which affects the overall visual appearance.

Thus, how to reduce the unnecessary seams on the exterior of the casing of the power supply so that the exterior of the power supply looks complete and comfortable is the current problem to be solved.

### SUMMARY

The disclosure provides a power supply with a novel appearance.

A power supply of the disclosure includes a first cover, a circuit board, and a second cover. The first cover has four first assembly holes, the circuit board is locked to the first assembly holes of the first cover, the second cover is closed with the first cover, and the circuit board is located in a space formed by the first cover and the second cover.

In an embodiment of the disclosure, the first cover has a top wall and a pair of first side walls. The first side walls are located on opposite sides of the top wall, a normal line direction of the top wall is perpendicular to a normal line direction of the pair of first side walls, and each of the first side walls is provided with a pair of the first assembly holes.

In an embodiment of the disclosure, a bottom edge of the each of the first side walls further has a first folded edge that is folded toward the inside of the first cover. A normal line direction of the first folded edge is parallel to the normal line direction of the top wall. The circuit board rests against the first folded edge and is locked to the first assembly holes.

In an embodiment of the disclosure, a side of the each of the first side walls further has a second folded edge that is folded toward the inside of the first cover. A normal line direction of the second folded edge is perpendicular to the normal line direction of the first folded edge and perpendicular to the normal line direction of the first side walls.

In an embodiment of the disclosure, each of the second folded edges has a pair of second assembly holes, and the second cover has multiple third assembly holes corresponding to the second assembly holes.

In an embodiment of the disclosure, the power supply further includes a fan assembled in the first cover. The top wall has multiple air holes. The fan is disposed corresponding to the air holes.

In an embodiment of the disclosure, the top wall further has multiple fourth assembly holes, and the fan is locked to the fourth assembly holes correspondingly.

In an embodiment of the disclosure, a connection between the top wall and the pair of first side walls is arc-shaped.

In an embodiment of the disclosure, the second cover has a bottom wall and a pair of second side walls, and the pair of second side walls are located on opposite sides of the bottom wall. When the second cover is closed with the first cover, the bottom wall faces the top wall, and the second side wall overlaps the second folded edge correspondingly.

In an embodiment of the disclosure, a connection between the bottom wall and the pair of second side walls is arc-shaped.

Based on the above, the outer casing of the power supply of the disclosure is simplified into two covers, reducing unnecessary casing seams, thus providing a novel and visually pleasing appearance.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is an exploded schematic diagram of a power supply of the disclosure.

FIG. 2 is an assembly diagram of the power supply of FIG. 1.

FIG. 3 is a schematic diagram of a fan assembled on a first cover of FIG. 1.

### DESCRIPTION OF THE EMBODIMENTS

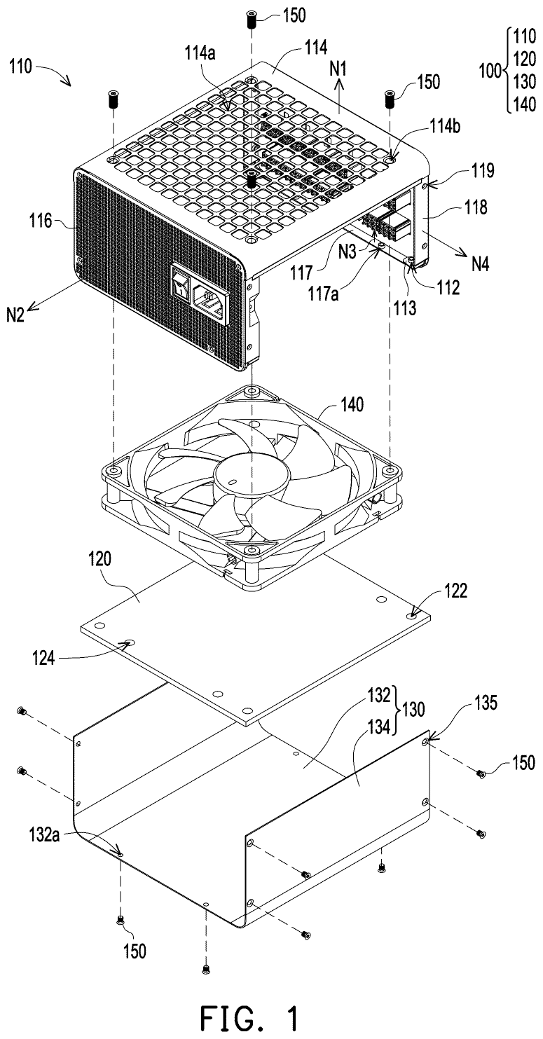

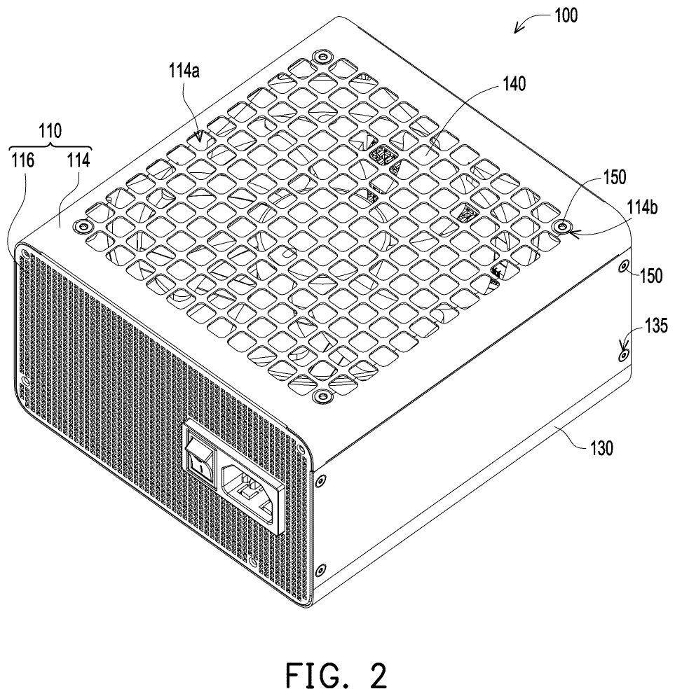

FIG. 1 is an exploded schematic diagram of a power supply of the disclosure, and FIG. 2 is an assembly diagram of the power supply of FIG. 1. Referring to FIG. 1 and FIG. 2 simultaneously, a power supply 100 includes a first cover 110, a circuit board 120, and a second cover 130. The first cover 110 has four first assembly holes 112. The circuit board 120 is locked to the first assembly hole 112 of the first cover 110. The second cover 130 is closed with the first cover 110. The circuit board 120 is located in the space formed by the first cover 110 and the second cover 130.

From the above, in the disclosure, by simplifying an outer casing of the power supply 100 into two (i.e., the first cover 110 and the second cover 130), it is possible to reduce the unnecessary casing seams in the exterior of the power supply 100, so as to make the power supply 100 appear complete in appearance.

Based on the above, the first cover 110 has a top wall 114 and a pair of first side walls 116. The first side walls 116 are located on opposite sides of the top wall 114, and a normal line direction N1 of the top wall 114 is perpendicular to a normal line direction N2 of the first side wall 116, and each of the first side walls 116 is provided with a pair of first assembly holes 112.

More specifically, the first assembly hole 112 is disposed at a folded edge 113 from the first side wall 116 toward the inside of the first cover 110.

A bottom edge of the each of the first side wall 116 also has a first folded edge 117 that is folded toward the inside of the first cover 110. A normal line direction N3 of the first folded edge 117 is parallel to the normal line direction N1 of the top wall 114. When the circuit board 120 is assembled to the first cover 110, the circuit board 120 rests against the first folded edge 117 and a fastener (such as a screw) 150 is locked into the first assembly hole 112 through a locking hole 122 of the circuit board 120 to lock the circuit board 120 into the first assembly hole 112.

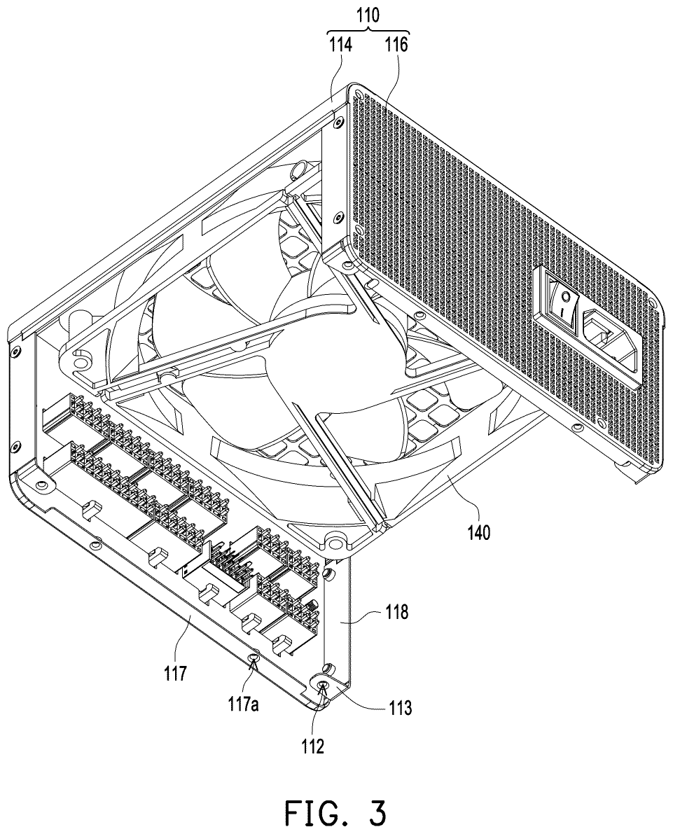

FIG. 3 is a schematic diagram of a fan assembled on a first cover of FIG. 1. Referring to FIG. 1 and FIG. 3 at the same time, a side of the each of the first side wall 116 also has a second folded edge 118 that is folded toward the inside of the first cover 110, a normal line direction N4 of the second folded edge 118 is perpendicular to the normal line direction N3 of the first folded edge 117 and perpendicular to the normal line direction N2 of the first side wall 116. In addition, each of the second folded edge 118 is provided with a pair of second assembly holes 119.

In this embodiment, the folded edge 113 is independent of the first folded edge 117 and is formed by further bending the second folded edge 118, but it is not limited thereto. In other embodiments not shown, the folded edge 113 may also be formed integrally with the first folded edge 117 and is independent of the second folded edge 118.

The second cover 130 has a bottom wall 132 and a pair of second side walls 134, and the second side walls 134 are located on opposite sides of the bottom wall 132. Specifically, the first side walls 116 of the first cover 110 are disposed on opposite sides of the top wall 114 in the normal line direction N2, and the second side walls 134 of the second cover are disposed on opposite sides of the bottom wall 132 in the normal line direction N4.

In addition, the second side walls 134 of the second cover 130 are provided with multiple third assembly holes 135 corresponding to the second assembly holes 119.

When the second cover 130 is closed with the first cover 110, the bottom wall 132 faces the top wall 114, the second side wall 134 overlaps the second folded edge 118 correspondingly, and the fastener (such as a screw) 150 is locked into the second assembly hole 119 through the third assembly hole 135 to assemble the second cover 130 with the first cover 110.

Referring to FIG. 1 and FIG. 2 at the same time, after the second cover 130 and the first cover 110 are assembled, the second side wall 134 covers a side opening of the first cover 110 that is not provided with a side wall from the outside of the first cover 110.

In addition, there is only the third assembly hole 135 on the second side wall 134 of the second cover 130, and the second side wall 134 covers the side opening of the first cover 110 that is not provided with a side wall from the outside of the first cover 110, and is assembled with the first cover 110 overlapping with the second folded edge 118. Thus, compared with the appearance of conventional power supplies, the appearance of the power supply 100 of this embodiment has fewer unnecessary casing seams and assembly holes, and the integrity of the appearance may make the user feel comfortable in the visual sense.

Incidentally, the first folded edge 117 is also provided with a first auxiliary assembly hole 117a, the bottom wall 132 of the second cover 130 has a second auxiliary assembly hole 132a, and the circuit board 120 has a third auxiliary assembly hole 124. The fastener (such as a screw) 150 is locked into the first auxiliary assembly hole 117a through the second auxiliary assembly hole 132a and the third auxiliary assembly hole 124 to secure the bottom wall 132 of the second cover 130, the circuit board 120, and the first folded edge 117 in a relative position with respect to each other.

Please continue to refer to FIG. 1, FIG. 2, and FIG. 3. The power supply 100 further includes a fan 140 assembled in the first cover 110, and the top wall 114 has multiple air holes 114a, where the fan 140 is disposed corresponding to the air holes 114a. Specifically, the top wall 114 has multiple fourth assembly holes 114b, the fan 140 is correspondingly locked to the fourth assembly hole 114b, and the circuit board 120 is located between the fan 140 and the bottom wall 132 of the second cover 130.

The fan 140 is configured to dissipate the heat generated by the heat source on the circuit board 120 to prevent heat from accumulating inside the power supply 100 and affecting the service life of the power supply 100 and the operation of the circuit board 120.

Incidentally, in this embodiment, the connection between the top wall 114 and the first side wall 116 is designed to be arc-shaped, and the connection between the bottom wall 132 and the second side wall 134 is also designed to be arc-shaped. The arc shape of the connection gives the power supply 100 a smooth streamlined appearance at the corners. Compared with the customary power supply, the corners of which are mostly presented in the form of right angles and have a rigid feeling, the power supply 100 of this embodiment has an arc shape due to the angular treatment of the connection, presenting a smooth sense of streamline design, which makes the power supply 100 of this embodiment have a softer sense of visual sensation and make people feel more comfortable.

To sum up, the power supply of the disclosure simplifies the outer casing into two covers, and one cover covers the joint structure of the other cover as much as possible, so that from the outward appearance, it is possible to minimize the unnecessary casing seams, and have a novel and visually pleasing appearance.

In addition, the circuit board in the power supply of the disclosure is locked to the first cover located on the upper side, which provides a novel arrangement structure, changes the assembly step flow, and facilitates assembly by the assembler.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A power supply, comprising:
a first cover, having four first assembly holes;
a circuit board, locked to the first assembly holes of the first cover; and
a second cover, closed with the first cover, wherein the circuit board is located in a space formed by the first cover and the second cover.

2. The power supply according to claim 1, wherein the first cover has a top wall and a pair of first side walls, the pair of first side walls are located on opposite sides of the top wall, a normal line direction of the top wall is perpendicular to a normal line direction of the pair of first side walls, and each of the first side walls is provided with a pair of the first assembly holes.

3. The power supply according to claim 2, wherein a bottom edge of the each of the first side walls further has a first folded edge that is folded toward the inside of the first cover, wherein a normal line direction of the first folded edge is parallel to the normal line direction of the top wall, and the circuit board rests against the first folded edge and is locked to the first assembly holes.

4. The power supply according to claim 3, wherein a side of the each of the first side walls further has a second folded edge that is folded toward the inside of the first cover, wherein a normal line direction of the second folded edge is perpendicular to the normal line direction of the first folded edge and perpendicular to the normal line direction of the first side walls.

5. The power supply according to claim 4, wherein each of the second folded edges has a pair of second assembly holes, and the second cover has a plurality of third assembly holes corresponding to the second assembly holes.

6. The power supply according to claim 2, further comprising a fan assembled in the first cover, the top wall having a plurality of air holes, and the fan being disposed corresponding to the air holes.

7. The power supply according to claim 6, wherein the top wall further has a plurality of fourth assembly holes, and the fan is locked to the fourth assembly holes correspondingly.

8. The power supply according to claim 2, wherein a connection between the top wall and the pair of first side walls is arc-shaped.

9. The power supply according to claim 4, wherein the second cover has a bottom wall and a pair of second side walls, and the pair of second side walls are located on opposite sides of the bottom wall, wherein when the second cover is closed with the first cover, the bottom wall faces the top wall, and the second side wall overlaps the second folded edge correspondingly.

10. The power supply according to claim 9, wherein a connection between the bottom wall and the pair of second side walls is arc-shaped.
